(19) United States
(12) Patent Application Publication
(10) Pub. No.: US 2016/0248050 A1
(43) Pub. Date: Aug. 25, 2016

(54) DEPOSITION APPARATUS

(71) Applicant: Samsung Display Co., Ltd., Yongin-si (KR)

(72) Inventors: Jae Sik KIM, Hwaseong-si (KR); Hyun Sung BANG, Bucheon-si (KR); Kyu Hwan HWANG, Yongin-si (KR)

(21) Appl. No.: 15/005,975

(22) Filed: Jan. 25, 2016

(30) Foreign Application Priority Data
Feb. 24, 2015 (KR) 10-2015-0026024

(51) Int. Cl. H01L 51/56; C23C 14/24; H01L 51/00

(52) U.S. Cl. CPC H01L 51/56; H01L 51/001; H01L 51/0011; C23C 14/24

(57) ABSTRACT

Disclosed is a deposition apparatus including: a deposition source heating a deposition material filled therein to vaporize the deposition material and including a plurality of nozzles spraying the vaporized deposition material toward a counter substrate; and a structure disposed between the deposition source and the substrate and including a plurality of angle adjustment plates arranged to have an opening in order to guide a movement direction of the deposition material sprayed from the nozzles, in which the angle adjustment plate is subjected to coating treatment by a self-assembled monolayer (SAM). Thereby, when a continuous deposition operation is performed, an organic material is not stacked on a structure such as an angle limitation plate or the angle adjustment plate.

### CROSS-REFERENCE TO RELATED APPLICATIONS

Any and all applications for which a foreign or domestic priority claim is identified in the Application Data Sheet as filed with the present application are hereby incorporated by reference under 37 CFR 1.57.

This application claims priority to and the benefit of Korean Patent Application No. 10-2015-0026024 filed in the Korean Intellectual Property Office on Feb. 24, 2015, the entire contents of which are incorporated herein by reference.

### BACKGROUND

1. Field

The present disclosure relates to a deposition apparatus, and more particularly, to a deposition apparatus depositing an organic layer structure on a panel of an organic light emitting diode (OLED) display.

2. Description of the Related Technology

Recently, an organic light emitting diode display (OLED) having excellent luminance and viewing angle characteristics and not requiring a separate light source portion unlike a liquid crystal display has received attention as a next-generation flat panel display. Since the organic light emitting diode display does not require a separate light source, the OLED display may be manufactured to be reduced in weight and thickness. Further, the OLED display has characteristics such as low power consumption, high luminance, and a high reaction speed.

Generally, the OLED display includes an organic light emitting element including an anode, an organic emission layer, and a cathode. In the organic light emitting element, holes and electrons are injected from the anode and the cathode, respectively, to form an exciton, and light is emitted while the exciton is transferred to a ground state. The anode and the cathode may be formed of a metal thin film or a transparent conductive thin film. The organic emission layer may be formed of at least one organic thin film. On a substrate of the OLED display, a deposition apparatus is used in order to form an organic thin film, a metal thin film, and the like. The deposition apparatus includes a crucible filled with a deposition material and a nozzle spraying the deposition material. If the crucible is heated to a predetermined temperature, the deposition material in the crucible is evaporated, and the evaporated deposition material is sprayed through the nozzle. The deposition material sprayed from the nozzle may be deposited on the substrate to form a thin film.

When an organic layer structure of the panel of the OLED is deposited, thermal evaporation is used, and in this case, a material evaporated in a deposition source moves to the substrate and is selectively deposited while passing through a deposition mask.

Herein, pixels implementing different colors such as red, green, and blue can be formed by selective deposition.

When the organic layer is deposited on the panel of the OLED, the organic material passing through the deposition mask passes through the mask in the deposition source to allow the organic material to contaminate another pixel other than the pixel to be deposited and hence does not result in a uniform deposition in the pixel where an angle of the organic material entering the pixel of the panel is low.

The lack of uniformity in the deposition thickness by formation of a shadow in the pixel is revealed in the form of stains and such, during lighting evaluation, and in cases where the organic material contaminates the other pixel to be deposited, color mixing occurs to make a different color.

### SUMMARY

The present disclosure has been made in an effort to provide a deposition apparatus reducing a shadow region.

Further, the present disclosure has been made in an effort to provide a deposition apparatus preventing thermal deformation of an organic material.

An exemplary embodiment provides a deposition apparatus including: a deposition source heating a deposition material filled therein to vaporize the deposition material and including a plurality of nozzles spraying the vaporized deposition material toward a counter substrate; and a structure disposed between the deposition source and the substrate and including a plurality of angle adjustment plates arranged to have an opening in order to guide a movement direction of the deposition material sprayed from the nozzles, in which the angle adjustment plate is subjected to coating treatment by a self-assembled monolayer (SAM).

The deposition apparatus may further include an angle limitation plate equipped in the deposition source to limit the movement direction of the deposition material sprayed from the nozzles, in which the angle limitation plate may be subjected to coating treatment by an SAM.

The SAM may include a head group, a hydrocarbon chain, and a terminal group, and silane may be used in the head group.

Radical reducing surface energy to form a hydrophobic state may be used in the terminal group.

The SAM may be the radical setting to form a contact angle of the terminal group to 90° or more.

The SAM may be coated by a vapor phase method or a liquid phase method.

The SAM may be deposited by any one of trichloro(1H,1H,2H,2H-perfluorooctyl)silane (FOTS), dichlorodimethylsilane (DDMS), and octadecyltrichlorosilane (OTS).

Another embodiment provides a deposition apparatus including: a deposition source heating a deposition material filled therein to vaporize the deposition material and including a plurality of nozzles spraying the vaporized deposition material toward a counter substrate; and an angle limitation plate equipped in the deposition source to limit a movement direction of the deposition material sprayed from the nozzles, in which the angle limitation plate may be subjected to coating treatment by a SAM.

The deposition apparatus according to the exemplary embodiment can greatly improve use efficiency of the deposition material.

Further, when a continuous deposition operation is performed, a washing operation should also be performed in order to remove the organic material stacked on the structure, and if the extent of organic material attached to the angle limitation plate or the structure is reduced by applying the exemplary embodiment, then accordingly washing operation may be reduced as well, thus reducing the washing cost.

Further, as compared to an existing heating structure, in the exemplary embodiment, probability of thermal deformation of the organic material is significantly lowered.

### BRIEF DESCRIPTION OF THE DRAWINGS

FIG. 1 is a schematic diagram of a deposition apparatus according to an exemplary embodiment.

FIG. 2 is a view illustrating an SAM structure that may be applied to the deposition apparatus according to the exemplary embodiment.

FIG. 3 is a view illustrating a process of applying an SAM on a bare glass in order to illustrate an example of a SAM coating method.

FIG. 4 is a graph of a contact angle of water to temperatures of liquid and vapor DDMS and liquid OTS.

### DETAILED DESCRIPTION

As the disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure. As used herein, the term “and/or” includes any and all combinations of one or more of the associated listed items.

Embodiments of the present disclosure will be described below in more detail with reference to the accompanying drawings. Those components that are the same or are in correspondence are rendered the same reference numeral regardless of the figure number, and redundant explanations are omitted.

It will be understood that although the terms “first”, “second”, etc. may be used herein to describe various components, these components should not be limited by these terms. These components are only used to distinguish one component from another. As used herein, the singular forms “a,” “an” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components. In the drawings, the thickness of layers, films, panels, regions, etc., are exaggerated for explanation. In other words, since sizes and thicknesses of components in the drawings are arbitrarily illustrated for convenience of explanation, the following embodiments are not limited thereto. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In addition, in the specification, unless explicitly described to the contrary, the word “comprise” and variations such as “comprises” or “comprising”, will be understood to imply the inclusion of stated elements but not the exclusion of any other elements.

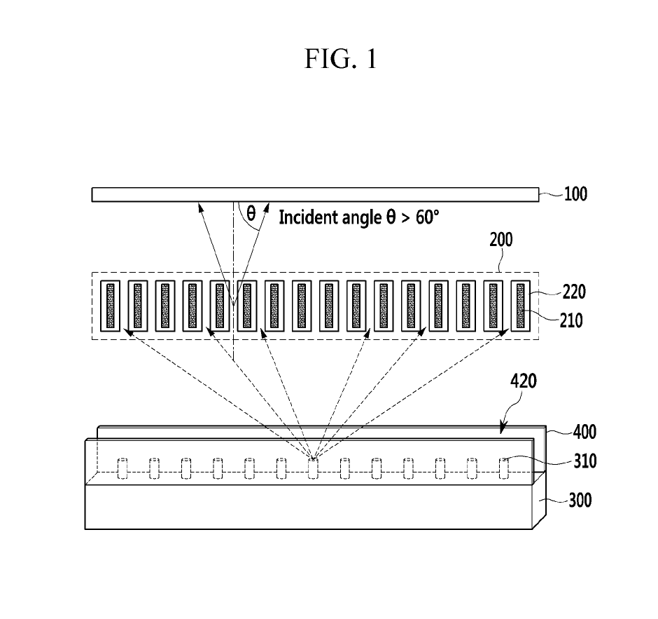

FIG. 1 is a schematic diagram of a deposition apparatus according to an exemplary embodiment.

Referring to FIG. 1, in the deposition apparatus according to the exemplary embodiment, self-assembled monolayers (SAM) 220 and 420 are applied on an angle adjustment plate 210 of a structure 200 or an angle limitation plate 400 equipped in a deposition source, such that it is possible to prevent an organic material from being attached to the angle adjustment plate 210 or the angle limitation plate 400 during a deposition operation of the organic material on a substrate 100.

Referring to FIG. 1, the deposition apparatus according to the embodiment includes a deposition source 300 heating a deposition material filled therein to vaporize the deposition material and including a plurality of nozzles 310 spraying the vaporized deposition material toward a counter substrate 100, and a structure 200 disposed between the deposition source 300 and the substrate 100 and including a plurality of angle adjustment plates 210 arranged to have an opening in order to guide a movement direction of the deposition material sprayed from the nozzles 310. Further, the deposition apparatus includes an angle limitation plate 400 equipped in the deposition source 300 to limit the movement direction of the deposition material sprayed from the nozzles 310.

The angle adjustment plate 210 and the angle limitation plate 400 are subjected to coating treatment by the SAMs 220 and 420.

If necessary, only any one of the angle limitation plate 400 and the angle adjustment plate 210 may be selectively used.

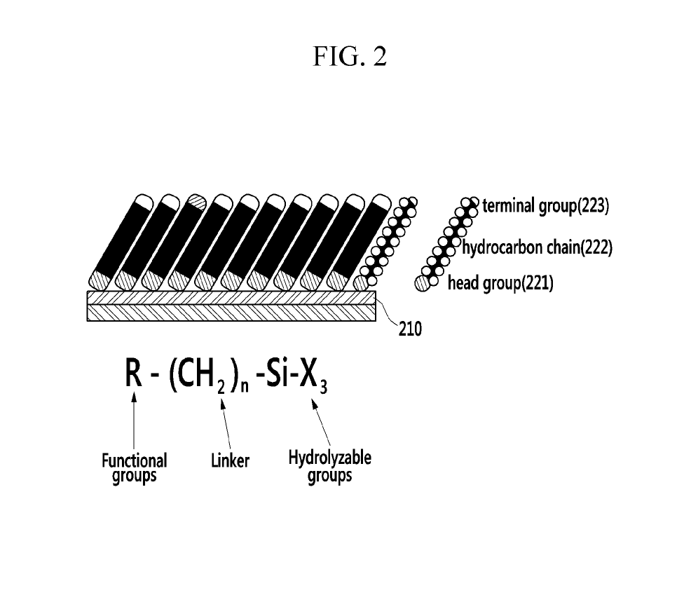

Referring to FIG. 2, the SAMs 220 and 420 applied on the angle adjustment plate 210 or the angle limitation plate 400 include a head group 221, a hydrocarbon chain 222, and a terminal group 223.

Silane may be used in the head group 221 to increase an adhesion property with the angle adjustment plate 210 or the angle limitation plate 400.

In the terminal group 223, a radical reducing surface energy to form a hydrophobic state may be used to prevent the organic material from being attached. The radical may allow a contact angle of the terminal group to be 90° or more.

The SAMs 220 and 420 may be deposited by a vapor phase method or a liquid phase method, and for example, any one of trichloro-(1H,1H,2H,2H-perfluorooctyl)silane (FOTS), octadecyltrichlorosilane (OTS), and dichlorodimethylsilane (DDMS) may be used as a precursor for coating of the monolayer by the vapor phase method.

Referring back to FIG. 1, an operation of the deposition apparatus according to the present exemplary embodiment will be described in more detail.

The deposition operation may be performed in a vacuum chamber (not illustrated), the vacuum chamber prevents a foreign particle from flowing from the outside, and a high vacuum state may be maintained in order to secure a straight property of the deposition material.

The deposition source 300 may be disposed at a lower portion. The organic material for being deposited on the substrate 100 and the like are filled therein. The deposition source 300 is configured to vaporize the organic material.

The deposition source 300 includes a plurality of nozzles 310 spraying the organic material to be deposited on the substrate 100. If the organic material is sprayed from the nozzle 310, the organic material moves in a direction of the structure 200 by being limited by the angle limitation plate 400.

Then, the organic material may pass through an opening between the angle adjustment plates 210 of the structure 200 to guide a movement direction at a predetermined angle.

Therefore, the organic material sprayed from the nozzle 310 may be deposited on a target point of the substrate.

Between the substrate 100 and the structure 200, a mask (not illustrated) having an opening pattern according to a deposition pattern formed on the substrate 100 may be provided, and in the present exemplary embodiment, a detailed description thereof will be omitted.

In the present exemplary embodiment, since the SAMs 220 and 420 are applied on the angle adjustment plate 210 of the structure 200 or the angle limitation plate 400 equipped in the deposition source 300, the organic material is hardly attached to the angle adjustment plate 210 or the angle limitation plate 400, and thus a shadow region is significantly reduced.

In addition, a washing operation of the angle limitation plate 400 or the angle adjustment plate 210 may not be required, or the number of washing operations may be significantly reduced.

Hereinafter, a coating process of the SAM 220 will be described in detail below.

In the exemplary embodiment, a SAM reaction using strong covalent bonding of a surface is used to manufacture the angle adjustment plate 210 of the structure 200 and the angle limitation plate 400.

The angle adjustment plate 210 and the angle limitation plate 400 may be formed of stainless steel, and may be any structure made of a material capable of covering, and as other examples, the angle adjustment plate and the angle limitation plate may be formed of iron (Fe), aluminum (Al), or the like.

In addition, on surfaces of the angle adjustment plate 210 and the angle limitation plate 400, an adhesion promoter inducing strong covalent bonding may be used.

In addition, as a X radical serving as a functional group, a material inducing hydrophobicity to reduce surface energy (i.e., increasing the contact angle) may be used to serve as a release.

The SAM of the exemplary embodiment may be applied by the liquid phase method (liquid phase deposition) or the vapor phase method (vapor phase deposition).

In the liquid phase method, the angle limitation plate 400 or the angle adjustment plate 210 as a target is dipped into a SAM solution, and a surface reaction is caused by dip coating, spin coating, and Langmuir-Blodgett (LB) methods, or the like to perform coating.

Generally, since a silane SAM such as tridecafluoro-(1,1,2,2)-tetrahydrooctyl-trichlorosilane(FOCS) is sensitive to moisture, a hydrophobic organic solvent is frequently used. Representative examples of the organic solvent include a material such as toluene and hexane.

If the vapor phase method is used, the hydrophobic solvent does permeate well in the corner portion of the hydrophilic surface or in the empty space in the nanoscale pattern effectively providing a SAM coating. In addition, the vapor phase method has the additional benefit of not utilizing a toxic solvent which is harmful to environment and health when the excess solvent used is discharged to waste.

After the SAMs 220 and 420 are applied, when the organic material is deposited, bouncing of the organic material occurs on the surface of the angle adjustment plate 210 or the angle limitation plate 400, and the amount of the organic material attached to the angle adjustment plate 210 or the angle limitation plate 400 is reduced.

Basically, in SAM coating, generally, the SAM including fluorine (F) is applied on the angle adjustment plate 210 or the angle limitation plate 400 to reduce the adhesion phenomenon.

A silane-SAM is also called a silane coupling agent, and, in inorganic sol-gel chemistry, is used for various purposes such as an increase in adherence, an increase in surface mechanical property, a dispersion stabilizer, catalyst immobilization, and surface immobilization of bio-materials.

Referring to FIG. 2, the most basic structure includes an X group for performing hydrolysis, a linker formed of a long alkyl chain, and R as a functionalized organic group.

The X group reacts with the surface, and hydrolyzed by water to be converted into a hydroxyl group (—OH) and then form a hydrogen bond together with another —OH group of an inorganic surface such as a silica particle, and the R group may provide functionality for a next reaction.

According to the number of X groups, when the number of X is three (X₃), the X group is trialkoxysilane, and when X is one, the X group is monoalkoxysilane. Further, according to the R group, various properties such as hydrophilicity, hydrophobicity, and bio-affinity can be provided.

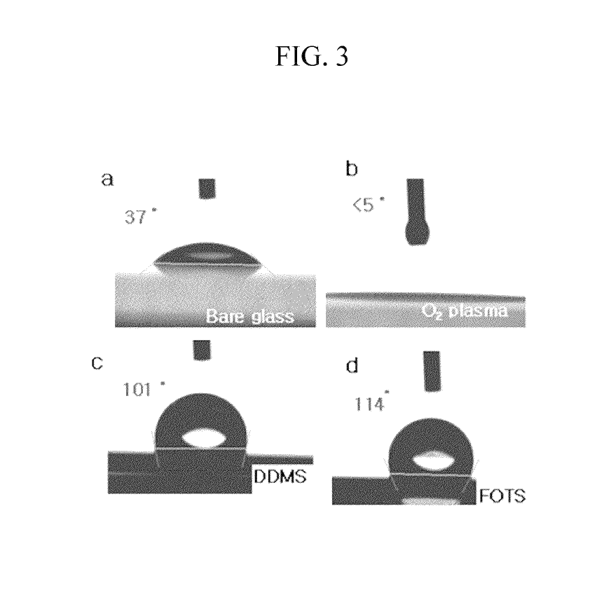

FIG. 3 is a view illustrating a process of applying a SAM on a bare glass in order to illustrate an example of a SAM coating method.

The surface of the bare glass has a contact angle of about 40° and surface energy of about 40 to 50 dyne/cm (a).

Before the silane SAM is deposited thereon, oxygen plasma treatment is performed for about 1 minute or more in order to activate the surface. Then, the surface of the angle limitation plate 400 or the angle adjustment plate 210 becomes hydrophilic and thus may be completely wet by water (b). In this case, surface energy is about 80 to 90 dyne/cm.

Then, in the case of treatment with DDMS and FOTS where a methyl group (—CH₃) and a trifluoromethyl group (—CF₃) are a terminal group, the surface of the angle limitation plate 400 or the angle adjustment plate 210 has a contact angle of 100° or more, and thus the surface becomes a hydrophobic surface.

In this case, surface energy is reduced to 20 dyne/cm or less, and thus DDMS and FOTS can be used as effective release agents (c, d).

Generally, it can be seen that the trifluoromethyl group exhibits the higher contact angle, and it is known that the contact angle is affected by homogeneity of the layer and uniformity of the surface, and in the case of FOTS, an ideal maximum contact angle is around about 120°.

In the case where DDMS having a short chain is used, as compared to a long chain trichlorosilane, the number of functional groups that react with the surface is two, and thus a risk of gel formation is relatively low.

After surface treatment, in a release test, there is no large difference between two materials of the methyl group (—CH₃) and the trifluoromethyl group (—CF₃) and both the two materials exhibit effective release characteristics.

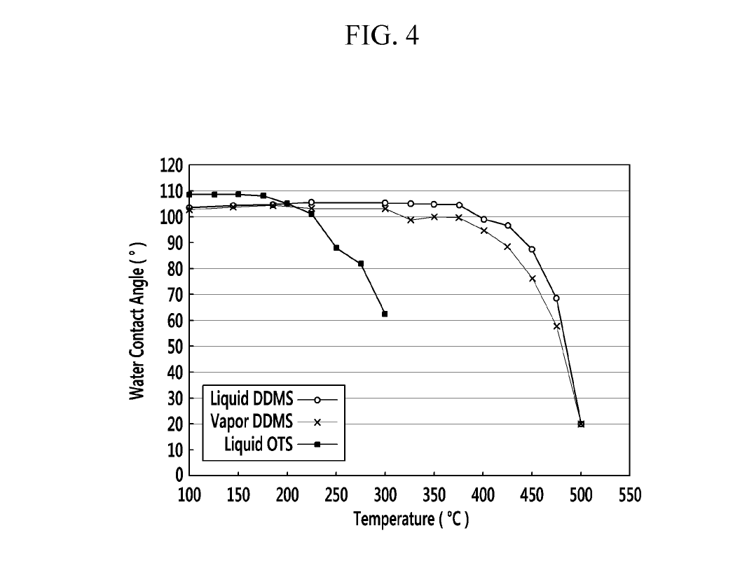

FIG. 4 is a graph of a contact angle of water to temperatures of liquid and vapor DDMS and liquid OTS.

Referring to FIG. 4, the contact angle of water at a low temperature is higher in the case of OTS than in DDMS. However, as is evident from the graph, OTS lacks stability at temperatures higher than 200° C., but DDMS exhibits thermal stability up to 400° C.

If a fluorine group is reacted with the organic material, degradation occurs, but the fluorine group is excellent in view of degassing with respect to the temperature. Therefore, when DDMS is applied to the angle limitation plate 400 positioned beside the nozzle 310, DDMS may endure a high temperature of the nozzle 310.

Like in the aforementioned exemplary embodiment, the angle limitation plate 400 or the surface of the structure 200 is conceptually subjected to a water-repellent coating.

In the head group of the SAM, silane is used to increase the adhesion property with the structure 200, and in the terminal group, the radical reducing surface energy to form a hydrophobic state is used to prevent the organic material from being adhered.

Therefore, an angle limitation function exists, but material efficiency is not reduced.

In addition, if a material that is incident on the angle limitation plate 400 or the angle adjustment plate 210 is not adhered, a proportion of the organic material contributing to deposition may be increased. In addition, even though the material is deposited on the angle limitation plate 400 or the angle adjustment plate 210, if a predetermined thickness or excess is formed, the material naturally falls in a downward direction and thus the path of the organic material entering between the angle adjustment plates 210 is not hindered.

Further, in the exemplary embodiment, during N-methyl-2-pyrrolidone (NMP) washing, chemical elimination with respect to the corresponding layer does not occur. In addition, there is no out gassing of the layer with respect to the temperature, and thus degradation of the organic material does not occur.

In conclusion, in the exemplary embodiment, very large improvement may be observed in view of material efficiency.

Further, when a continuous deposition operation is performed, a washing operation should be performed in order to remove the organic material stacked on the structure, and if the organic material is less adhered to the angle limitation plate 400 or the structure 200 by applying the exemplary embodiment, less washing may be required, and thus effectively reducing the washing costs.

Further, as compared to an existing heating structure, in the exemplary embodiment, probability of thermal deformation of the organic mate to increase material efficiency by 1%, and when only the angle limitation plate 400 next to the nozzle 310 exists without the structure 200, material efficiency is 20 to 40%.

Herein, when stainless steel (SUS304) is inserted as the structure 200, according to a simulation result, material efficiency is reduced to 10 to 30%.

In this case, when the structure 200 is subjected to coating of the SAM 220, material efficiency is increased to the same level as material efficiency when there is no structure 200.

In addition, when the angle limitation plate 400 is subjected to coating of the SAM 420, it is expected that material efficiency of 40% or higher can be achieved.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A deposition apparatus comprising:
a deposition source heating a deposition material filled therein to vaporize the deposition material and including a plurality of nozzles spraying the vaporized deposition material toward a counter substrate; and
a structure disposed between the deposition source and the substrate and including a plurality of angle adjustment plates arranged to have an opening in order to guide a movement direction of the deposition material sprayed from the nozzles,
wherein the angle adjustment plate is subjected to coating treatment by a self-assembled monolayer (SAM).

2. The deposition apparatus of claim 1, further comprising:
an angle limitation plate equipped in the deposition source to limit the movement direction of the deposition material sprayed from the nozzles,
wherein the angle limitation plate is subjected to coating treatment by an SAM.

3. The deposition apparatus of claim 1, wherein:
the SAM includes a head group, a hydrocarbon chain, and a terminal group, and silane is used in the head group.

4. The deposition apparatus of claim 3, wherein:
a radical reducing surface energy to form a hydrophobic state is used in the terminal group.

5. The deposition apparatus of claim 4, wherein:
the radical allows a contact angle of the terminal group to be 90° or more.

6. The deposition apparatus of any one of claims 1, wherein:
the SAM is coated by a vapor phase method or a liquid phase method.

7. The deposition apparatus of claim 6, wherein:
the SAM is deposited by any one of trichloro-(1H,1H,2H,2H perfluorooctyl)silane (FOTS), dichlorodimethylsilane (DDMS), and octadecyltrichlorosilane (OTS).

8. A deposition apparatus comprising:
a deposition source heating a deposition material filled therein to vaporize the deposition material and including a plurality of nozzles spraying the vaporized deposition material toward a counter substrate; and
an angle limitation plate equipped in the deposition source to limit a movement direction of the deposition material sprayed from the nozzles,
wherein the angle limitation plate is subjected to coating treatment by a SAM.
